(19) United States
(12) Patent Application Publication
(10) Pub. No.: US 2017/0168025 A1
(43) Pub. Date: Jun. 15, 2017

(54) DEVICE IN WHICH ELEMENT IS PROVIDED ON SUBSTRATE HAVING PENETRATING WIRE AND MANUFACTURING METHOD THEREFOR

(71) Applicant: CANON KABUSHIKI KAISHA, Tokyo (JP)

(72) Inventors: Shinan Wang, Komae-shi (JP); Yutaka Setomoto, Sagamihara-shi (JP)

(21) Appl. No.: 15/374,894

(22) Filed: Dec. 9, 2016

(30) Foreign Application Priority Data
Dec. 15, 2015 (JP) 2015-244644

(51) Int. Cl. G01N 29/24; H01L 41/25; H01L 41/047

(52) U.S. Cl. CPC G01N 29/2418; H01L 41/047; H01L 41/25; G01N 29/2406

(57) ABSTRACT

A manufacturing method for a device includes a step of forming a through hole configured to extend from a first surface of a substrate to a second surface located on a side opposite from the first surface, a step of forming an insulating film on a surface of the substrate including an inner wall of the through hole, a step of filling the through hole with a conductive material so that the conductive material is in contact with the insulating film formed on the inner wall, a step of polishing the first surface of the substrate so that the conductive material filled in the through hole does not protrude from a surface of the insulating film on the surface of the substrate, and a step of forming an element to be connected to the conductive material on the polished first surface of the substrate.

### BACKGROUND OF THE DISCLOSURE

Field of the Disclosure

The present disclosure generally relates to a device in which an element is provided on a substrate having a penetrating wire and a manufacturing method for the device.

Description of the Related Art

A penetrating wire is used to improve functionality for small size, high speed, and multi-function of a device such as an electronic device, a semiconductor device, or an optical device. The penetrating wire can electrically connect chips that constitute the device or an element on a front surface of a substrate and an electrode pad on a back surface of the substrate at the shortest distance. The formation methods for the penetrating wire are roughly classified into a via first process in which a penetrating wire is formed before formation of an element and a via last process in which a penetrating wire is formed after formation of an element. The via first process allows a high-quality insulating film to be deposited on a surface of a substrate including an inner wall of a through hole at high temperature, and therefore, is suitable for a device that requires high dielectric strength. However, when a temperature increasing process is needed to form the element, it is necessary to consider thermal diffusion from the material of the penetrating wire to the substrate and the influence on the element due to the difference in thermal expansion between the penetrating wire and the substrate.

To reduce thermal diffusion, a barrier can be formed. To reduce the difference in thermal expansion, a penetrating wire can be formed of a material similar to that of the substrate. For example, when the substrate is formed of silicon (Si), the penetrating wire can be formed of polysilicon doped with phosphorus. On the other hand, the penetrating wire formed of polysilicon has high resistivity. To reduce the resistivity of the penetrating wire, the penetrating wire is desirably formed of metal when the element can be formed at relatively low temperature. For example, the substrate is formed of silicon, and the penetrating wire is formed of copper (Cu). In this case, since the thermal expansion coefficient of Cu is six or more times as high as that of silicon, when the temperature increases or decreases during formation of the element, the penetrating wire expands and contracts or slides relative to an inner wall of a through hole in which the penetrating wire fits. Owing to such relative movement, when the temperature increases, an end face of the penetrating wire protrudes from the surface of the substrate, and this may cause permanent deformation or breakage of a thin film that forms the element. Further, when the temperature decreases, the penetrating wire pulls the thin film while restoring, and may cause permanent deformation, breakage, or the increase in stress of the thin film near the end face. Such permanent deformation, breakage, or increase in stress of the thin film causes a defect of the element and performance unevenness of the element. Although the element can be disposed at a position apart from the penetrating wire in order to ensure performance of the element, this reduces the degree of integration of the element. To reduce permanent deformation, breakage, or increase in stress of the thin film, it is necessary to suppress relative movement of the penetrating wire resulting from the temperature change on the surface of the substrate on which the element is provided.

Japanese Patent Laid-Open No. 2013-46006 discloses a manufacturing method using a via last process for a penetrating wire structure whose width decreases from a surface of a substrate on which an element is not provided toward a surface of the substrate on which an element is provided. In such a penetrating wire structure, restraint imposed on the surface of the penetrating wire by an inner wall of a through hole is stronger on the surface provided with the element than on the surface provided with no element. Hence, movement of the penetrating wire relative to the substrate due to the temperature change is smaller on the surface of the substrate provided with the element than on the surface of the substrate provided with no element inside the through hole.

However, the manufacturing method disclosed in Japanese Patent Laid-Open No. 2013-46006 adopts the via last process, and was devised to improve embeddability of the penetrating wire and an insulating ring surrounding the penetrating wire. Hence, on the surface provided with the element, the end face of the penetrating wire protrudes from the surface of the substrate into the thin film that forms the element. When such a structure is applied to the via first process, the end face of the penetrating wire on the surface provided with the element thermally expands and contracts in the temperature increasing/decreasing process during formation of the element, and this may cause permanent deformation or breakage of the thin film that forms the element. Accordingly, the present disclosure generally provides a device manufacturing method that suppresses, for example, deformation of an element occurring in a temperature increasing/decreasing process during formation of the element.

### SUMMARY OF THE DISCLOSURE

According to an aspect of the present disclosure, there is provided a manufacturing method for a device in which an element is provided on a substrate having a penetrating wire, the manufacturing method including: a step of forming a through hole configured to extend from a first surface of the substrate to a second surface located on a side opposite from the first surface, a step of forming an insulating film on a surface of the substrate including an inner wall of the through hole, a step of filling the through hole with a conductive material so that the conductive material is in contact with the insulating film formed on the inner wall, and a step of forming the element so that the element is connected to the conductive material on the first surface of the substrate, wherein a width of the through hole is smaller on the first surface than on the second surface.

According to another aspect of the present disclosure, there is provided a device in which an element is provided on a substrate having a penetrating wire, the device including the penetrating wire formed of a conductive material and configured to extend from a first surface of the substrate toward a second surface located on a side opposite from the first surface, an insulating film including an area in contact with the penetrating wire inside the substrate and also located on the first surface of the substrate, and the element provided on the first surface of the substrate and connected to the conductive material, wherein a width of the through hole is smaller on the first surface than on the second surface.

Further features of the present disclosure will become apparent from the following description of exemplary embodiments with reference to the attached drawings.

### BRIEF DESCRIPTION OF THE DRAWINGS

FIGS. 1A to 1F are cross-sectional views illustrating a device manufacturing method.

FIGS. 2A to 2F are cross-sectional views illustrating the device manufacturing method.

FIG. 3 is a plan view illustrating a device manufacturing method according to a first exemplary embodiment.

FIGS. 4A to 4K are cross-sectional views illustrating the device manufacturing method according to the first exemplary embodiment.

FIGS. 5A to 5F are cross-sectional views illustrating a device manufacturing method according to a second exemplary embodiment.

FIGS. 6A and 6B are plan views illustrating an application example of the device of the present disclosure.

### DESCRIPTION OF THE EMBODIMENTS

The present disclosure is based on the findings that, in a device in which an element is provided on a substrate having a penetrating wire, permanent deformation or breakage is mainly caused in a thin film that forms the element by relative movement of the penetrating wire along a lengthwise direction of a through hole on a first surface of the substrate provided with the element (that is, a direction perpendicular to a first surface and a second surface of the substrate). Of such relative movement, a relative movement of an end face of the penetrating wire resulting from the temperature change is particularly significant. In the present disclosure, the structure of the through hole is devised to suppress relative movement of the penetrating wire on the first surface of the substrate provided with the element and to thereby reduce damage to the thin film that forms the element.

While an embodiment of the present disclosure will be described below with reference to the drawings, the present disclosure is not limited to such an embodiment, and various modifications and changes can be made within the scope of the disclosure.

### EMBODIMENT

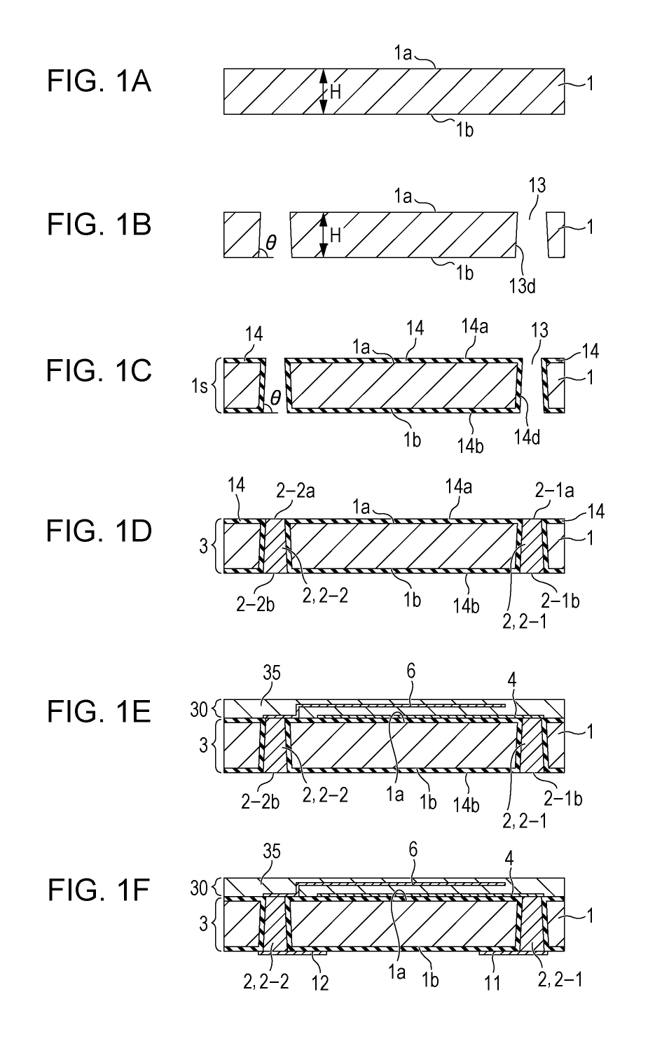

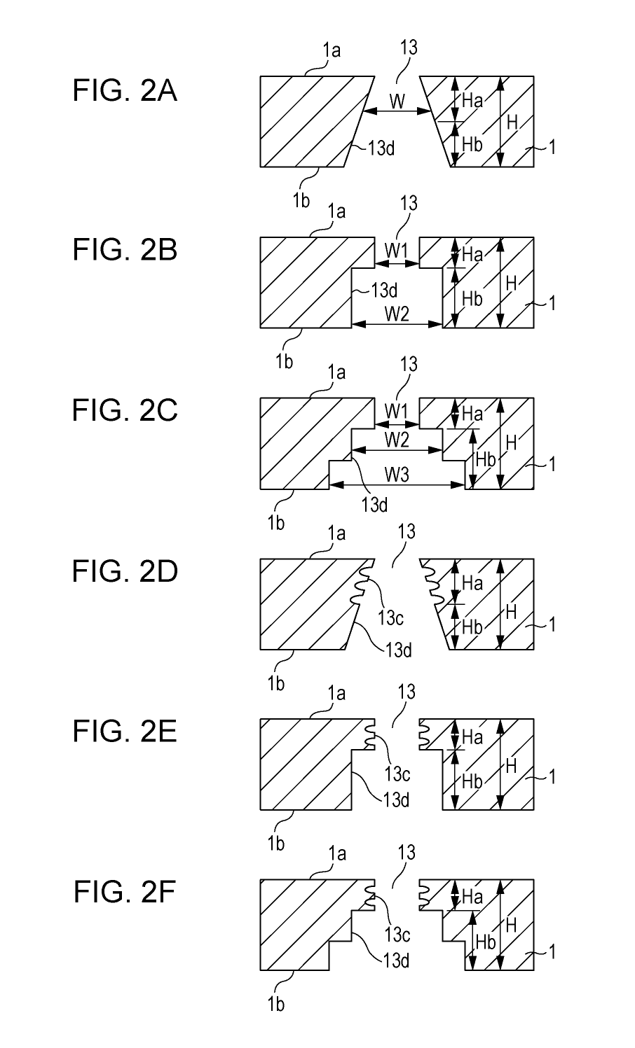

A manufacturing method for a device according to an embodiment of the present disclosure will be described with reference to cross-sectional views of FIGS. 1A to 1F and 2A to 2F. In manufacture of a device, it is general to form a plurality of penetrating wires or a plurality of elements on one substrate at the same time. However, FIGS. 1A to 1F illustrate only two penetrating wires and one element for simple and easy view. The manufacturing method for the device according to the embodiment of the present disclosure typically includes the following steps. A through hole is formed in a substrate to extend from a first surface of the substrate to a second surface located on a side opposite from the first surface. Here, the step of forming the through hole may be replaced with a step of preparing a substrate having a through hole. The through hole is machined so that the width thereof is the smallest on the first surface. Then, an insulating film is formed on a surface of the substrate including an inner wall of the through hole. A conductive material is filled inside the through hole to be in contact with the insulating film formed on the inner wall of the through hole, and is polished so that end faces of the conductive material does not protrude from the first and second surfaces of the substrate including the insulating film. Thus, a penetrating wire is formed. Then, an element is formed on the first surface of the substrate, and an electrode pad is formed on the second surface of the substrate.

First, as illustrated in FIG. 1A, a substrate 1 is prepared. The substrate 1 is formed of a semiconductor material like a silicon (Si) substrate. The substrate 1 has a first surface 1a and a second surface 1b located on a side opposite from the first surface 1a, and the first surface 1a and the second surface 1b are flat and mirror-polished. A thickness H of the substrate 1 can be within the range of, for example, 50 to 1000 μm.

Next, as illustrated in FIG. 1B, through holes 13 are formed in the substrate 1. The through holes 13 extend from the first surface 1a to the second surface 1b, and penetrate the substrate 1. For example, the number and positions of the through holes 13 and the shape and size of openings are defined by a photoresist pattern according to the intended use. For example, the openings of the through holes 13 on the first surface 1a of the substrate 1 are circular, and have a diameter within the range of 20 to 100 μm. For example, the openings are arranged in an array having a period of 200 μm in a lateral direction and a period of 2 mm in a longitudinal direction. Here, the through holes 13 are machined so that their width is the smallest (narrowest) on the first surface 1a. Such a structure mainly aims to suppress relative movement of penetrating wires 2 (see FIGS. 1D to 1F) along the lengthwise direction of the through holes 13 on the first surface 1a and to thereby reduce damages to a thin film that forms an element. However, the shape of inner walls 13d of the through holes 13 is not limited as long as a sufficient effect can be obtained. Further, the inner walls 13d of the through holes 13 may have surface irregularities (including surface undulation and surface roughness).

For example, the through holes 13 may have any of section shapes illustrated in FIGS. 2A to 2F. In FIG. 2A, the inner wall 13d of each through hole 13 is inversely tapered, and the width W thereof gradually increases from the first surface 1a toward the second surface 1b. That is, the width W gradually decreases from the second surface 1b toward the first surface 1a. In FIG. 2B, the inner wall 13d of the through hole 13 has two stages, and the width W of the through hole 13 is nearly uniform (W=W1) in a part Ha on the first surface 1a side. On the other hand, the width W of the through hole 13 is nearly uniform (W=W2) in a part Hb on the second surface 1b side. However, W1 is less than W2. That is, the width W of the through hole 13 is smaller (narrower) in the part Ha on the first surface 1a side than in the part Hb on the second surface 1b side. In FIG. 2C, the inner wall 13d of the through hole 13 has multiple stages (three or more stages, only three stages are illustrated in FIG. 2C). The width W (=W1) of the through hole 13 is the smallest in a part Ha on the first surface 1a side (W1<W2<W3, . . . ). Here, the width W decreases in a stepwise manner (steplike manner). In FIGS. 2A to 2C, the inner wall 13d of the through hole 13 is substantially smooth, and the maximum height of the surface irregularities is, for example, 0.5 μm or less. When only a part of the reference length in the direction of the average line of the height is extracted from a measured roughness curve, the sum of the height of the highest peak from the average line in the extracted part and the depth of the lowest bottom from the average line represents the maximum height of the surface irregularities. For example, the reference length is double the period (or average interval) of a surface undulation component in the surface irregularities. The reference length is, for example, 20 μm with respect to the surface roughness component in the surface irregularities. FIGS. 2D to 2F illustrate through hole structures in which surface irregularities 13c are provided in the parts Ha of the inner walls 13d of the through holes 13 illustrated in FIGS. 2A to 2C. In FIGS. 2D to 2F, the maximum height of the surface irregularities 13c in the parts Ha is, for example, 2 μm or more. When one period (or average interval) of the surface irregularities 13c is designated as p, it is preferable that 10p≧Ha≧1p, and more preferable that 5p≧Ha≧2p. For example, p is about 5 μm, and 25 μm≧Ha≧10 μm. Also, it is preferable that the length of each part Ha should be equal to or less than ⅕ of the length H of the through hole 13 (or the thickness of the substrate 1), that is, that Ha≦⅕H. As required, the inner wall 13d of the through hole 13 is smoothed to smooth sharp portions on the inner wall 13d of the through hole 13 including the peaks of the surface irregularities 13c. Smoothing is performed to avoid electric field concentration larger than the reference concentration on the inner wall 13d of the through hole 13. A description will be given below of an example in which the inner wall 13d of the through hole 13 has an inverse tapered shape in consideration of easy explanation. The angle formed by the inner wall 13d of the through hole 13 on the second surface 1b and the second surface 1b of the substrate 1 is designated as θ. In principle, the effect is exerted as long as θ<90°. However, when the angle θ is too large (for example, 88°<θ<90°), the effect is insufficient. In contrast, when the angle θ is too small (for example, θ<) 60°, restraint force on the penetrating wire 2 (see FIG. 1D) imposed by the inner wall 13d of the through hole 13 is weakened on the second surface 1b side, and the penetrating wire 2 may fall off from the through hole 13 when the temperature increases or decreases. Also, machining of the through hole 13 becomes difficult. Accordingly, it is preferable that 60°≦θ≦88°. More preferably, 75°≦θ≦85°. The through hole 13 is machined using, for example, depth reactive ion etching (RIE) of Si including a Bosch process. In RIE, a desired shape of the inner wall 13d of the through hole 13 is realized by adjusting the machining conditions such as the gas flow rate, chamber pressure, etching power, bias power, and etching time. After machining, the inner wall 13d of the through hole 13 is smoothed as required. Smoothing is performed by thermal oxidation of the surface of the substrate 1 formed of Si and removal of a thermal oxide film.

Next, as illustrated in FIG. 1C, an insulating film 14 is formed on the surface of the substrate 1 including the first surface 1a, the second surface 1b, and the inner walls 13d of the through holes 13 (see FIG. 1B). For example, a thermal oxide film of Si is used as the insulating film 14. The Si thermal oxide film is formed by heating the substrate 1 having the through holes 13, which is formed in the step of FIG. 1B, at high temperature in an oxygen atmosphere. When the insulating film 14 is formed, a surface 14a of the insulating film 14 serves as a new surface of the first surface 1a of the substrate 1, and a surface 14b of the insulating film 14 serves as a new surface of the second surface 1b of the substrate 1. Also, a surface 14d of the insulating film 14 serves as new inner walls of the through holes 13. The substrate 1 having the structure of FIG. 1C is referred to as a through-hole substrate 1s. Here, the step of FIG. 1B of forming the through holes and the step of FIG. 1C of forming the insulating film can be respectively replaced with a step of preparing a substrate having through holes and a step of preparing a substrate having an insulating film. This case is regarded as being within the scope specified by the present disclosure.

Next, as illustrated in FIG. 1D, penetrating wires 2 (including 2-1 and 2-2) are formed inside the through holes 13 of the through-hole substrate 1s (see FIG. 1C). To form the penetrating wires 2, first, a conductive material 2 is filled inside the through holes 13 to be in contact with the surface 14d (see FIG. 1C) of the insulating film 14 formed on the inner walls 13d of the through holes 13. As the filling method, for example, embedding of conductive paste or plating with a conductive material is used. The conductive material 2 is planarized by polishing to form penetrating wires 2. Planarization is performed so that end faces 2-1a and 2-2a of the penetrating wires 2 do not protrude from the surface 14a of the insulating film 14 on the first surface 1a side of the substrate 1 and so that end faces 2-1b and 2-2b of the penetrating wires 2 do not protrude from the surface 14b of the insulating film 14 on the second surface 1b side of the substrate 1. For planarization, for example, chemical mechanical polishing (CMP) is used. The through-hole substrate 1s (see FIG. 1C) in which the penetrating wires 2 are formed is referred to as a through-hole wiring board 3.

Next, as illustrated in FIG. 1E, an element 30 is formed on the first surface 1a of the substrate 1 (that is, on the surface 14a of the insulating film 14). For example, the element 30 is composed of an electrode portion (including a first electrode 4 and a second electrode 6) and a remaining portion 35. The first electrode 4 and the second electrode 6 are formed of a metal material. The first electrode 4 is electrically connected to the end face 2-1a of the penetrating wire 2 (see FIG. 1D), and the second electrode 6 is electrically connected to the end face 2-2a of the penetrating wire 2 (see FIG. 1D). For example, the element 30 is any of various types of micro electro mechanical system (MEMS) elements. More specifically, the element 30 is, for example, a capacitive micromachined ultrasonic transducer (CMUT). The structure of the element 30 is designed according to the specifications of the device to be manufactured. In the formation process of the element 30, heating to 100° C. or more is sometimes needed. In this case, movement of the penetrating wires 2 relative to the inner walls 14d of the through holes 13 (see FIG. 1C) occurs in proportion to the amount of change in temperature caused by the increase or decrease in temperature. The relative movement of the penetrating wires 2 is substantially proportional to the amount of change in temperature. On the first surface 1a of the substrate 1 on which the element 30 is formed, the width of the inner walls 14d (see FIG. 1C) of the through holes 13 including the insulating film 14 is smaller (narrower) than on the second surface 1b. Hence, the inner walls 14d more strongly restrain the surfaces of the penetrating wires 2. In contrast, since the width of the inner walls 14d (see FIG. 1C) of the through holes 13 including the insulating film 14 is larger (wider) on the second surface 1b of the substrate 1 on which the element 30 is not formed, the restraint on the surfaces of the penetrating wires 2 is weak. For this reason, the relative movement of the penetrating wires 2 when the temperature increases and decreases is suppressed on the first surface 1a of the substrate 1 where the element 30 is provided, and is released on the second surface 1b of the substrate 1 where the element 30 is not provided. That is, relative movement of the end faces of the penetrating wires 2 (including 2-1a and 2-2a, see FIG. 1D) on the first surface 1a provided with the element 30 is suppressed. As a result, the risk of permanent deformation or breakage of the thin film that forms the element 30 (including the first electrode 4, the second electrode 6, and the remaining portion 35) is reduced near the end faces of the penetrating wires 2.

Next, as illustrated in FIG. 1F, electrode pads (including 11 and 12) are formed on the second surface 1b of the substrate 1 (that is, on the surface 14b of the insulating film 14). The electrode pad 11 is electrically connected to the end face 2-1b of the penetrating wire 2 (see FIG. 1E), and the electrode pad 12 is electrically connected to the end face 2-2b of the penetrating wire 2 (see FIG. 1E). The main component of the electrode pad 11 and the electrode pad 12 is metal. For example, the electrode pad 11 and the electrode pad 12 are each composed of a titanium (Ti) thin film serving as an adhesion layer and an aluminum (Al) thin film formed on the Ti thin film. For example, the formation method for the electrode pads 11 and 12 includes sputter film deposition of metal, formation of an etching mask using photolithography, and etching of the metal. In these steps, the maximum temperature of the substrate is about 100° C. Movement of the penetrating wires 2 relative to the inner walls 14d (see FIG. 1C) of the through holes 13 resulting from the increase or decrease in temperature is smaller than when the element 30 is formed. Further, since the metal thin film has relatively high extensibility, permanent deformation or breakage of the electrode pads 11 and 12 due to stress can be reduced further. Therefore, in the formation process of the electrode pads, permanent deformation or breakage of the thin film of the element 30 and the metal film of the electrode pads 11 and 12 rarely occurs.

Next, although not illustrated, the device (including the element 30, the through-hole wiring board 3, and the electrode pads 11 and 12) manufactured through the steps of FIGS. 1A to 1F is connected to a control circuit. Connection is made using the electrode pads 11 and 12. Examples of connection methods include direct metal bonding, bump bonding, anisotropic conductive film (ACF) bonding, and wire bonding.

By using the above-described manufacturing method, the device illustrated in FIG. 1F can be manufactured. According to this manufacturing method, when the temperature increases or decreases to form the element, movement of the end face of the penetrating wire relative to the inner wall of the through hole is suppressed on the first surface provided with the element, and this reduces the risk of permanent deformation or breakage of the thin film that forms the element on the periphery of the penetrating wire. As a result, near the penetrating wire, the thin film that forms the element is also rarely broken, and is in excellent in uniformity of film thickness and membrane stress. Thus, the element can be disposed near the penetrating wire, and as a result, the degree of integration of the element increases. Further, the risk of permanent deformation or breakage of the inner wall of the through hole and the thin film formed on the inner wall is also reduced, and this enhances electric reliability of the device. Hereinafter, the present disclosure will be described in detail with reference to specific exemplary embodiments.

### EXEMPLARY EMBODIMENTS

### First Exemplary Embodiment

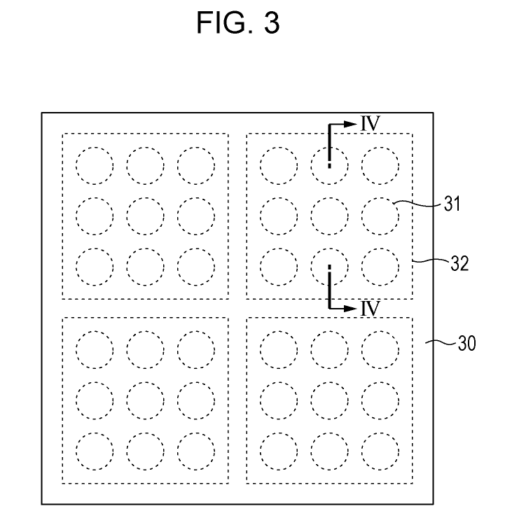

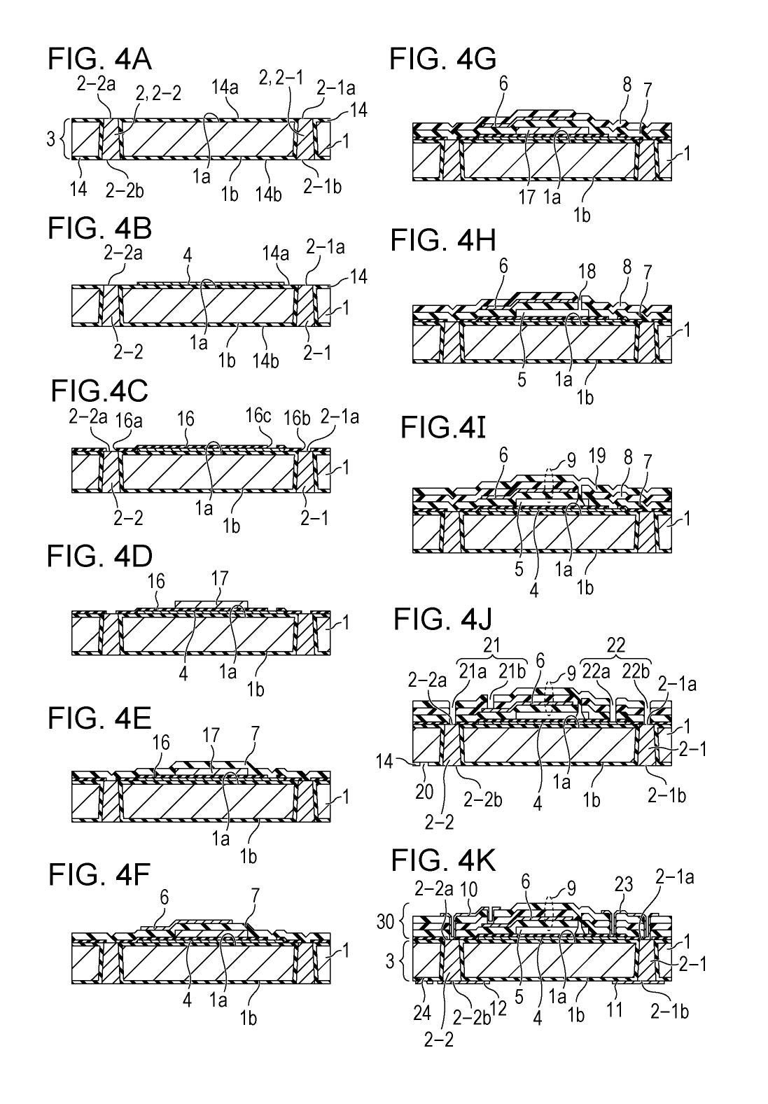

Here, an example of a method for manufacturing a CMUT on a through-hole wiring board by a via first process will be described with reference to a plan view of FIG. 3 and cross-sectional views of FIGS. 4A to 4K. A CMUT is a capacitive transducer that can transmit and receive acoustic waves, such as ultrasonic waves, by using vibrations of a vibration film, and can easily obtain excellent broadband characteristics particularly in the liquid. The CMUT has a cell including a pair of electrodes, and obtains electric signals based on the change in electrostatic capacitance between the pair of electrodes. In practice, as illustrated in the plan view of FIG. 3, in one CMUT device, a plurality of vibration films (also referred to as “cells”) 31 arranged in a two-dimensional array constitute one element part 32, and a plurality of element parts 32 are arranged on a substrate to constitute an element 30, so that desired performance is achieved. To independently control the element parts 32, penetrating wires are formed in correspondence to the element parts 32. Section structures of FIGS. 4A to 4K illustrating a manufacturing process for the CMUT are taken along line IV-IV of FIG. 3. For simplicity, only one cell (one vibration film) and two penetrating wires in the CMUT are illustrated in FIGS. 4A to 4K. In the CMUT of the first exemplary embodiment, as illustrated in FIG. 4K, an element 30 is provided on a first surface 1a (first side) of a substrate 1, and electrode pads (including 11, 12, and 24) are provided on a second surface 1b (second side) of the substrate 1. Penetrating wires 2 (including 2-1 and 2-2) are electrically connected to the element 30 on the first surface 1a of the substrate 1, and are electrically connected to the electrode pads 11 and 12 on the second surface 1b of the substrate 1. The element 30 has a cell including a first electrode 4, a second electrode 6 provided with a gap 5 between the first electrode 4 and the second electrode 6, and a vibration film 9 capable of vibration and composed of insulating films (including 7, 8, and 19) disposed on upper and lower sides of the second electrode 6. The first electrode 4 is connected to the electrode pad 11 via a penetrating wire 2-1. The second electrode 6 is connected to the electrode pad 12 via a penetrating wire 2-2. Also, the substrate 1 is connected to the electrode pad 24.

The manufacturing process for the CMUT will be described below. First, as illustrated in FIG. 4A, a through-hole wiring board 3 is prepared. The through-hole wiring board 3 is formed by a method similar to the method illustrated in FIGS. 1A to 1D. A substrate 1 is a Si substrate. The substrate 1 has a first surface 1a and a second surface 1b, and these two surfaces are mirror-polished to have a surface roughness Ra less than 2 nm. The substrate 1 has a resistivity of about 0.01 Ω·cm and a thickness of about 300 μm. Through holes 13 (see FIG. 1C) have a diameter of 50 μm on the first surface 1a, and are arranged in an array having a period of 400 μm in the lateral direction and a period of 2 mm in the longitudinal direction. Inner walls 13d of the through holes 13 are inversely tapered from the first surface 1a toward the second surface 1b, and have an angle θ of about 85°. After machining of the through holes 13, the inner walls 13d of the through holes 13 are smoothed, and the curvature diameter of an envelope of crest peaks (or trough bottoms) of surface irregularities on the inner walls 13d is 5 μm or more. A thermal oxide film 14 having a thickness of about 1 μm and made of Si is formed as an insulating film on the inner walls 13d of the through holes 13. Inside the through holes 13, penetrating wires 2 (including 2-1 and 2-2) are formed to be in tight contact with a surface 14d of the insulating film 14 formed on the inner walls 13d of the through holes 13. The penetrating wires 2 are mainly composed of Cu, and are formed by electroplating (electric plating) of Cu. End faces (including 2-1a, 2-1b, 2-2a, and 2-2b) of the penetrating wires 2 are planarized by CMP. Planarization prevents the end faces 2-1a and 2-2a of the penetrating wires 2 from protruding from a surface 14a of the insulating film 14 on the first surface 1a of the substrate 1. Planarization also prevents the end faces 2-1b and 2-2b of the penetrating wires 2 from protruding from a surface 14b of the insulating film 14 on the second surface 1b of the substrate 1. Two penetrating wires 2 are formed in each one element part 32 of the CMUT (see FIG. 3).

Next, as illustrated in FIG. 4B, a first electrode 4 is formed on the first surface 1a of the substrate 1. The first electrode 4 is one of electrodes for driving a vibration film 9 (see FIG. 4K). Since the first electrode 4 is formed on the thermal oxide film 14 made of Si, it is insulated from the substrate 1. The first electrode 4 is located under a vibrating portion of the vibration film 9 in the cell (a portion corresponding to a gap 5 in FIG. 4K), and extends around from the vibrating portion of the vibration film 9. The first electrode 4 is conductively connected to each cell in the same element part. The first electrode 4 is formed by a laminate of a thin film made of Ti and having a thickness of about 10 nm and a thin film made of W and having a thickness of about 50 nm. The first electrode 4 is formed by a method including film deposition of metal, formation of an etching mask using photolithography, and etching of the metal.

Next, as illustrated in FIG. 4C, a pattern of an insulating film 16 is formed. The insulating film 16 covers the surface of the first electrode 4, and one of the functions thereof is to serve as an insulating protection film for the first electrode 4. The insulating film 16 is a thin film made of Si oxide and having a thickness of 200 nm. The Si oxide thin film is formed by CVD at a substrate temperature of about 300° C. After the Si oxide film is deposited, apertures 16a, 16b, and 16c are formed in the insulating film 16. The apertures 16a, 16b, and 16c are formed by a method including formation of an etching mask using photolithography and dry etching using reactive ion etching.

Next, as illustrated in FIG. 4D, a sacrificial layer 17 is formed. The sacrificial layer 17 is used to form the gap 5 in the cell, and is formed of chromium (Cr). The thickness and shape of the sacrificial layer 17 are determined by the required CMUT characteristics. First, a Cr film having a thickness of 200 nm is formed on the first surface 1a of the substrate 1 by an electron beam vapor deposition method. Then, the Cr film is machined into a desired shape by a method including photolithography and wet etching. The sacrificial layer 17 has a columnar structure having a diameter of about 30 μm and a height of about 200 nm, and is connected to an etch hole 18 to be formed in the step of FIG. 4H.

Next, as illustrated in FIG. 4E, an insulating film 7 is formed. The insulating film 7 is in contact with a lower surface of a second electrode 6 to be formed in the step of FIG. 4F, and one of the functions thereof is to serve as an insulating protection film for the second electrode 6. The insulating film 7 is a Si nitride having a thickness of 400 nm. The Si nitride thin film is deposited by plasma enhanced chemical vapor deposition (PE-CVD) at a substrate temperature of about 300° C. During film deposition, for example, the flow rate of deposition gas is controlled so that the Si nitride film to become the insulating film 7 has a tensile stress of about 0.1 GPa.

Next, as illustrated in FIG. 4F, a second electrode 6 is formed. The second electrode 6 is formed on the vibration film 9 (see FIG. 4K) to be opposed to the first electrode 4, and is one of the electrodes for driving the vibration film 9. The second electrode 6 is formed by a laminate of a Ti film having a thickness of 10 nm and an aluminum-neodymium (AlNd) alloy film having a thickness of 100 nm stacked in this order. The second electrode 6 is formed by a method including sputter film deposition of metal, formation of an etching mask using photolithography, and etching of the metal. The film deposition conditions of the second electrode 6 are adjusted so that the second electrode 6 has a tensile stress of 0.4 GPa or less at a time point when manufacture of the CMUT is completed. The second electrode 6 is formed to be conductively connected to each cell in the same element part.

Next, as illustrated in FIG. 4G, an insulating film 8 is formed. The insulating film 8 covers an upper surface of the second electrode 6, and one of the functions thereof is to serve as an insulating protection film for the second electrode 6. The insulating film 8 has a structure similar to that of the insulating film 7, and is formed by a method similar to that for the insulating film 7.

Next, as illustrated in FIG. 4H, an etch hole 18 is formed and the sacrificial layer 17 is removed. The etch hole 18 is formed by a method including photolithography and reactive ion etching. The sacrificial layer 17 formed of Cr (see FIG. 4G) is removed by introducing an etching solution through the etch hole 18. Thus, a gap 5 having the same shape as the sacrificial layer 17 is formed.

Next, as illustrated in FIG. 4I, a thin film 19 is formed. The thin film 19 seals the etch hole 18, and also constitutes a vibration film 9 capable of vibrating on an upper side of the gap 5 together with the insulating film 7, the second electrode 6, and the insulating film 8. The thin film 19 is a Si nitride having a thickness of 800 nm. Similarly to the insulating film 7, the thin film 19 is deposited by PE-CVD at a substrate temperature of about 300° C. The vibration film 9 formed in this way has a tensile stress of about 0.7 GPa as a whole, and is structured to be unsusceptible to sticking or buckling and breakage. Further, the structure (including material, thickness and stress) of the vibration film 9 is designed according to the required CMUT characteristics. The above-described structure of the vibration film 9 is just an example for explaining the manufacturing method.

Next, as illustrated in FIG. 4J, a contact hole 20, contact holes 21 (including 21a and 21b) and 22 (including 22a and 22b) are formed for electric connection. The contact hole 20 is an opening formed in the second surface 1b of the substrate 1 so that the second surface 1b is partly exposed therethrough. The contact holes 21 and 22 are formed in the first surface 1a of the substrate 1. The end face 2-2a of the penetrating wire 2-2 is partly exposed through the contact hole 21a, and the surface of the second electrode 6 is partly exposed through the contact hole 21b. The surface of the first electrode 4 is partly exposed through the contact hole 22a, and the end face 2-1a of the penetrating wire 2-1 is partly exposed through the contact hole 22b. For example, the contact hole 20 is formed by a method including formation of an etching mask using photolithography and etching of Si thermal oxide by buffered hydrofluoric acid (BHF). The contact holes 21 and 22 are formed by a method including formation of an etching mask using photolithography and reactive ion etching of Si nitride. For example, the contact holes 20, 21, and 22 are shaped like a column having a diameter of about 10 μm.

Next, as illustrated in FIG. 4K, connection wires 10 and 23 and electrode pads 11, 12, and 24 are formed. The connection wires 10 and 23 are formed on the first surface 1a of the substrate 1 by stacking a Ti film having a thickness of about 10 nm and an Al film having a thickness of about 500 nm in this order. The connection wire 10 electrically connects the second electrode 6 and the end face 2-2a of the penetrating wire 2-2 via the contact holes 21 (including 21a and 21b, see FIG. 4J). The connection wire 23 electrically connects the first electrode 4 and the end face 2-1a of the penetrating wire 2-1 via the contact holes 22 (including 22a and 22b, see FIG. 4J). The electrode pads 11, 12, and 24 are formed on the second surface 1b of the substrate 1, and are each formed by an Al film having a thickness of about 500 nm. The electrode pad 11 is formed to be connected to the end face 2-1b of the penetrating wire 2-1. The electrode pad 12 is formed to be connected to the end face 2-2b of the penetrating wire 2-2. As a result, the first electrode 4 provided on the first surface 1a of the substrate 1 is extended to the second surface 1b of the substrate 1 via the penetrating wire 2-1. Similarly, the second electrode 6 provided on the first surface 1a of the substrate 1 is extended to the second surface 1b of the substrate 1 via the penetrating wire 2-2. The electrode pad 24 is formed to be connected to the substrate 1.

In the above-described formation process for the insulating films 7, 8, and 19, the surface of the lower layer film may be subjected to plasma treatment before deposition of the upper layer film in order to enhance adhesion between the films. By this plasma treatment, the surface of the lower layer film is cleaned or activated. Next, although not illustrated, the CMUT manufactured through the steps of FIGS. 4A to 4K is connected to a control circuit. The connection is made using the electrode pads 11, 12, and 24. As the connection method, anisotropic conductive film (ACF) bonding is used. In the CMUT manufactured by the above-described manufacturing method, in one element part 32, at least one of the first electrode and the second electrode in each cell is electrically connected. During driving, bias voltage is applied to the first electrode 4, and the second electrode 6 is used as a signal application electrode or a signal take-out electrode. Signal noise can be reduced by grounding the substrate 1 via the electrode pad 24. In the above-described steps, the maximum temperature of the substrate 1 is about 300° C.

### Second Exemplary Embodiment

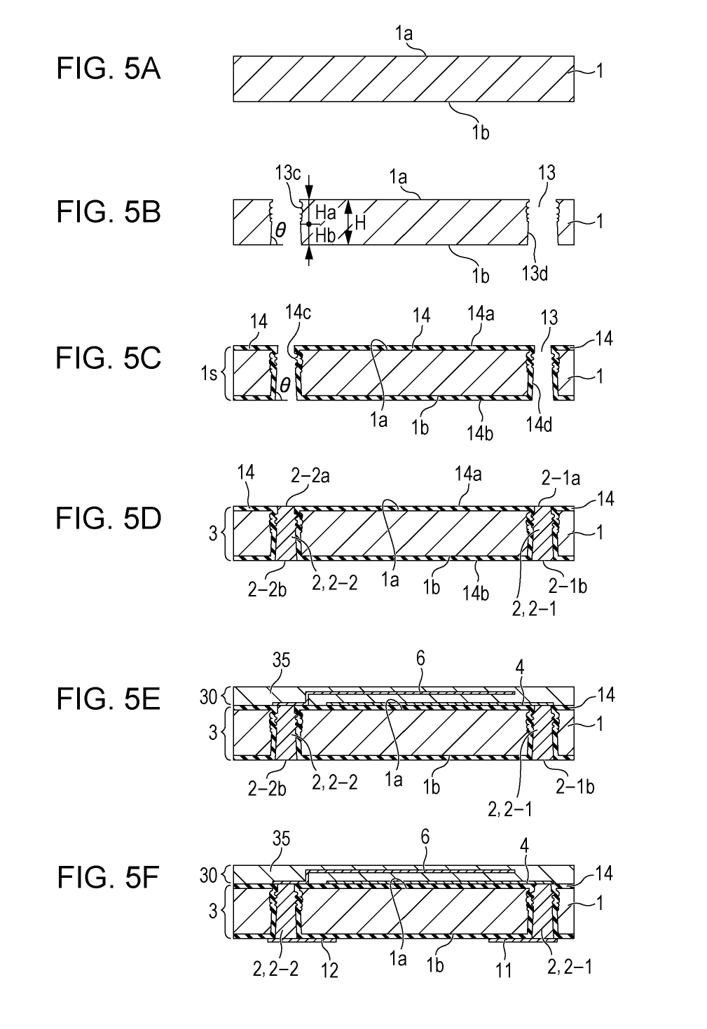

Here, a description will be given of a method for manufacturing a device on a through-hole wiring board by a via first process, with reference to cross-sectional views of FIGS. 5A to 5F.

First, as illustrated in FIG. 5A, a substrate 1 is prepared. The substrate 1 is a Si substrate. The substrate 1 has a first surface 1a and a second surface 1b, and these two surfaces are mirror-polished to have a surface roughness Ra less than 2 nm. The substrate 1 has a resistivity of about 0.01 Ω·cm and a thickness of about 300 μm.

Next, as illustrated in FIG. 5B, through holes 13 are formed in the substrate 1. The through holes 13 extend from the first surface 1a to the second surface 1b of the substrate 1, and penetrate the substrate 1. The through holes 13 have a diameter of 30 μm on the first surface 1a, and are arranged in an array having a period of 400 μm in the lateral direction and a period of 2 mm in the longitudinal direction. The through holes 13 are machined by depth RIE of Si using a Bosch process. In RIE, the machining conditions are adjusted so that inner walls 13d of the through holes 13 have a substantially inverse tapered shape and the angle θ of the inner walls 13d of the through holes 13 is about 85°. The inner walls 13d of the through holes 13 are provided with scallops as surface irregularities 13c in parts Ha on the first surface 1a side. One period (or average interval) of the surface irregularities 13c is about 5 μm, and the length of Ha is about 20 μm. The surface irregularities 13c may be formed simultaneously with formation of the tapered shape of the through holes 13. Alternatively, the surface irregularities 13c may be formed after the through holes 13 are formed into the tapered shape. After the surface irregularities 13c are formed, the inner walls 13d of the through holes 13 are smoothed, and sharp portions on the inner walls 13d of the through holes 13 including peaks of the scallops are smoothed. Smoothing is performed by thermal oxidation of the surface of the substrate 1 made of Si and removal of the thermal oxide film. Smoothing is performed so that, after an insulating film 14 of FIG. 5C is formed, the curvature diameter of an envelope of crest peaks (or trough bottoms) of the surface irregularities 14c in the through holes 13 including the insulating film 14 becomes 5 μm or more. After smoothing, the maximum height of the scallops in the parts Ha on the first surface 1a side is about 5 μm. In contrast, the maximum height of scallops on the inner walls 13d of the through holes 13 in parts Hb on the second surface 1b side is 0.5 μm or less.

Next, as illustrated in FIG. 5C, a thermal oxide film 14 made of Si and having a thickness of 1 μm is formed as an insulating film on the surface of the substrate 1 including the first surface 1a, the second surface 1b, and the inner walls 13d of the through holes 13 (see FIG. 5B). The Si thermal oxide film 14 is formed by heating the substrate 1 having the through holes 13 formed in the step of FIG. 5B to about 1000° C. in an oxygen atmosphere. A surface 14d of the Si thermal oxide film 14 forms new inner wall surfaces of the through holes 13. The substrate 1 having the structure of FIG. 5C is referred to as a through-hole substrate 1s.

Next, as illustrated in FIG. 5D, penetrating wires 2 (including 2-1 and 2-2) are formed inside the through holes 13 of the through-hole substrate is (see FIG. 5C). The penetrating wires 2 are formed to be in tight contact with the surface 14d of the insulating film 14 formed on the inner walls 13d of the through holes 13. The penetrating wires 2 are formed by using electroplating of Cu and CMP. On the first surface 1a of the substrate 1, end faces 2-1a and 2-2a of the penetrating wires 2 do not protrude from a surface 14a of the insulating film 14 after CMP. On the second surface 1b of the substrate 1, end faces 2-1b and 2-2b of the penetrating wires 2 do not protrude from a surface 14b of the insulating film 14. The through-hole substrate is in which the penetrating wires 2 are formed (see FIG. 5C) is referred to as a through-hole wiring board 3.

Next, as illustrated in FIG. 5E, an element 30 is formed on the first surface 1a of the substrate 1. The element 30 is composed of an electrode part (including a first electrode 4 and a second electrode 6) and a remaining part 35. The electrodes are formed of a metal material. The first electrode 4 is electrically connected to the end face 2-1a of the penetrating wire (see FIG. 5D), and the second electrode 6 is electrically connected to the end face 2-2a of the penetrating wire (see FIG. 5D). The element 30 is a CMUT as an example.

Next, as illustrated in FIG. 5F, electrode pads (including 11 and 12) are formed on the second surface 1b of the substrate 1. The electrode pad 11 is electrically connected to the end face 2-1b of the penetrating wire 2 (see FIG. 5E), and the electrode pad 12 is electrically connected to the end face 2-2b of the penetrating wire 2 (see FIG. 5E). The electrode pads 11 and 12 are each formed by a laminate of a thin film made of Ti and having a thickness of about 10 nm and a thin film made of Al and having a thickness of about 500 nm. The electrode pads 11 and 12 are formed by a method including sputter film deposition of metal, formation of an etching mask using photolithography, and etching of the metal.

Next, although not illustrated, the device manufactured through the steps of FIGS. 5A to 5F (including the element 30, the through-hole wiring board 3, and the electrode pads 11 and 12) is connected to a control circuit. Connection is made using the electrode pads 11 and 12 by ACF bonding.

In the formation process of the element 30, heating to a maximum of about 300° C. is sometimes needed. On the first surface 1a of the substrate 1 on which the element 30 is provided, the width of the inner walls 14d of the through holes 13 (see FIG. 5C) including the insulating film 14 is smaller. Hence, the inner walls 14d restrain the surfaces of the penetrating wires 2 more firmly. Further, the surfaces of the penetrating wires 2 and the surfaces 14d of the inner walls of the through holes 13 (see FIG. 5C) are fitted together by surface irregularities 14c (see FIG. 5C) on the inner walls of the through holes 13 in the parts Ha on the first surface 1a side. Hence, in the parts Ha, the surfaces of the penetrating wires 2 are restrained more firmly. In contrast, on the second surface 1b of the substrate 1 on which the element 30 is not provided, the width of the inner walls 14d of the through holes 13 including the insulating film 14 (see FIG. 5C) is larger, and the surface irregularities are smaller. Hence, restraint on the surfaces of the penetrating wires 2 is weaker. For this reason, when the temperature increases or decreases, relative movement of the penetrating wires 2 is suppressed on the first surface 1a of the substrate 1 provided with the element 30, but concentrates on the second surface 1b of the substrate 1 on which the element 30 is not provided. That is, movement of the end faces (including 2-1a and 2-2a, see FIG. 5D) of the penetrating wires 2 on the first surface 1a of the substrate 1 provided with the element 30 relative to the inner walls of the through holes is even smaller than when the surface irregularities 14c are nor provided. As a result, near the end faces (including 2-1a and 2-2a, see FIG. 5D) of the penetrating wires 2, the risk of permanent deformation or breakage of the thin film that forms the element 30 is reduced further.

The surface irregularities 14c (see FIG. 5C) on the inner walls of the through holes 13 also have the following function. That is, when the temperature changes, the surface irregularities 14c suppress the penetrating wires 2 (see FIGS. 5D to 5F) from falling off from the through holes 13 (see FIG. 5C). In general, the penetrating wires 2 made of metal do not have high adhesion to the inner walls 14d of the through holes 13 made of semiconductor oxide or the like. Further, the penetrating wires 2 are greatly different in thermal expansion coefficient from the inner walls 14d. For this reason, there was an example in which the penetrating wires 2 fell off from the through holes 13 when the temperature greatly changed. In the present embodiment, the surface irregularities 14c are formed on the inner walls of the through holes 13 so that the surfaces of the penetrating wires 2 and the surfaces of the inner walls 14d (see FIG. 5C) of the through holes 13 are fitted together in the parts Ha on the first surface 1a side. Such a fitting structure can prevent the above-described fall.

### Third Exemplary Embodiment

Here, a description will be given of application examples of the devices (CMUT) manufactured in the first and second exemplary embodiments. The CMUT manufactured in the first exemplary embodiment can be applied to a subject information acquisition apparatus using acoustic waves, such as an ultrasonic diagnosis apparatus or an ultrasound image forming apparatus. By receiving acoustic waves from a subject by the CMUT and using output electric signals, subject information that reflects the optical characteristic values of the subject, such as the optical absorption coefficient, and subject information that reflects the difference in acoustic impedance can be acquired.

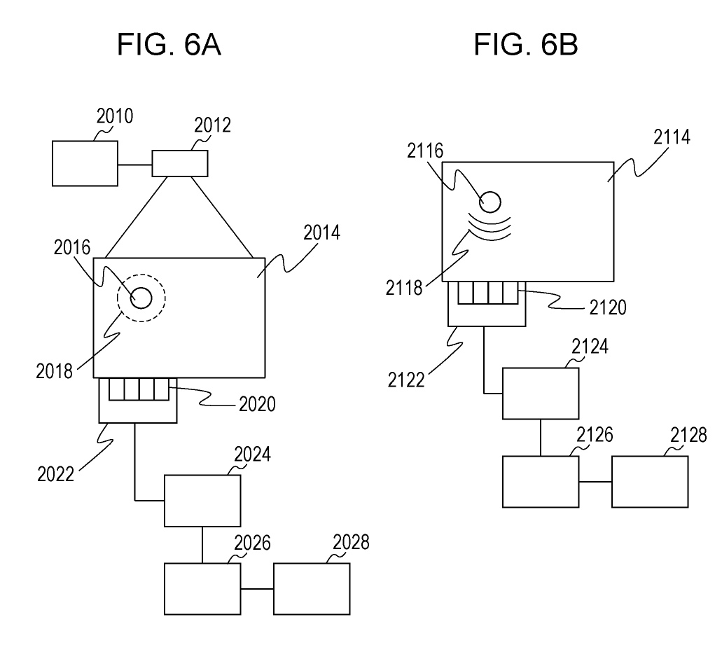

FIG. 6A illustrates an example of a subject information acquisition apparatus using the photoacoustic effect. Pulse light emitted from a light source 2010 is applied to a subject 2014 via an optical member 2012 such as a lens, a mirror, or an optical fiber. An optical absorber 2016 provided inside the subject 2014 absorbs energy of the pulse light, and generates a photoacoustic wave 2018 serving as an acoustic wave. A device 2020 including an electromechanical transducer (CMUT) manufactured according to the present embodiment is provided inside a probe 2022. The device 2020 receives the photoacoustic wave 2018, converts the photoacoustic wave 2018 into an electric signal, and outputs the electric signal to a signal processing unit 2024. The signal processing unit 2024 conducts signal processing, such as A/D conversion or amplification, on the input electric signal, and outputs the processed electric signal to a data processing unit 2026. The data processing unit 2026 acquires subject information (characteristic information that reflects the optical characteristic values of the subject, for example, the optical absorption coefficient) as image data by using the input signal. Here, the signal processing unit 2024 and the data processing unit 2026 are generically referred to as a processing unit. A display unit 2028 displays an image based on the image data input from the data processing unit 2026. As described above, the subject information acquisition apparatus of the third exemplary embodiment includes the electronic device of the present disclosure, the light source, and the processing unit. The electronic device receives a photoacoustic wave generated by irradiation of the subject with the light emitted from the light source and converts the photoacoustic wave into an electric signal, and the processing unit acquires information about the subject by using the electric signal.

FIG. 6B illustrates a subject information acquisition apparatus such as an ultrasonic echo diagnosis apparatus using reflection of an acoustic wave. An electronic device 2120 including an electromechanical transducer (CMUT) of the present disclosure is provided inside a probe 2122. An acoustic wave transmitted from the electronic device 2120 to a subject 2114 is reflected by a reflector 2116. The electronic device 2120 receives a reflected acoustic wave (reflected wave) 2118, converts the acoustic wave into an electric signal, and outputs the electric signal to a signal processing unit 2124. The signal processing unit 2124 conducts signal processing, such as A/D conversion or amplification, on the input electric signal, and outputs the processed electric signal to a data processing unit 2126. The data processing unit 2126 acquires subject information (characteristic information that reflects the difference in acoustic impedance) as image data by using the input signal. Here, the signal processing unit 2124 and the data processing unit 2126 are also generically referred to as a processing unit. A display unit 2128 displays an image based on the image data input from the data processing unit 2126. As described above, the subject information acquisition apparatus of the third exemplary embodiment includes the electronic device manufactured according to the present disclosure, and the processing unit that acquires subject information by using the electric signal output from the electronic device. The electronic device receives an acoustic wave from the subject and outputs an electric signal.

The probe may be mechanically scanned or may be moved relative to the subject by a user such as a doctor or an engineer (handheld type). In the case of the apparatus of FIG. 6B using the reflected wave, a probe for transmitting an acoustic wave may be provided separately from a probe for receiving the acoustic wave. Further, both subject information that reflects the optical characteristic values of the subject and subject information that reflects the difference in acoustic impedance may be acquired by combining the functions of both the apparatus of FIG. 6A and the apparatus of FIG. 6B. In this case, the device 2020 of FIG. 6A may perform not only receiving of the photoacoustic wave but also transmission of the acoustic wave and receiving of the reflected wave.

The above-described CMUT can also be used in a measurement apparatus that measures the magnitude of external force. Here, the magnitude of external force applied to the surface of the CMUT is measured using an electric signal from the CMUT. While the CMUT is used in the third exemplary embodiment, a piezoelectric transducer can be used instead of the CMUT.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2015-244644, filed Dec. 15, 2015, which is hereby incorporated by reference herein in its entirety.

What is claimed is:

1. A manufacturing method for a device in which an element is provided on a substrate having a penetrating wire, the manufacturing method comprising:
a step of forming a through hole configured to extend from a first surface of the substrate to a second surface located on a side opposite from the first surface;
a step of forming an insulating film on a surface of the substrate including an inner wall of the through hole;
a step of filling the through hole with a conductive material so that the conductive material is in contact with the insulating film formed on the inner wall; and
a step of forming the element so that the element is connected to the conductive material on the first surface of the substrate,
wherein a width of the through hole is smaller on the first surface than on the second surface.

2. The manufacturing method for the device according to claim 1, further comprising:
a step of polishing the first surface of the substrate so that the conductive material filled in the through hole does not protrude from a surface of the insulating film on the surface of the substrate.

3. The manufacturing method for the device according to claim 1, wherein the width of the through hole gradually decreases from the second surface toward the first surface.

4. The manufacturing method for the device according to claim 3, wherein an angle θ formed between the inner wall of the through hole and the second surface is within a range such that 60°≦θ≦88°.

5. The manufacturing method for the device according to claim 4, wherein the angle θ is within a range such that 75°≦θ≦85°.

6. The manufacturing method for the device according to claim 1, wherein the width of the through hole decreases in a stepwise manner from the second surface toward the first surface.

7. The manufacturing method for the device according to claim 2, further comprising:
a step of polishing a part of the conductive material protruding from the through hole after the step of filling the conductive material.

8. The manufacturing method for the device according to claim 1, wherein the device is a transducer including a cell having a pair of electrodes and configured to obtain an electric signal based on a change in electrostatic capacitance between the pair of electrodes.

9. A device in which an element is provided on a substrate having a penetrating wire, comprising:
the penetrating wire formed of a conductive material and configured to extend from a first surface of the substrate toward a second surface located on a side opposite from the first surface;
an insulating film including an area in contact with the penetrating wire inside the substrate and also located on the first surface of the substrate; and
the element provided on the first surface of the substrate and connected to the conductive material,
wherein a width of a through hole is smaller on the first surface than on the second surface.

10. The device according to claim 9, wherein the penetrating wire formed inside the through hole does not protrude from a surface of the insulating film on the first surface.

11. The device according to claim 9, wherein the device is a transducer including a cell having a pair of electrodes and configured to obtain an electric signal based on a change in electrostatic capacitance between the pair of electrodes.

12. The device according to claim 9, wherein the element is a piezoelectric transducer.

13. A subject information acquisition apparatus, comprising:
the device according to claim 11; and
a processing unit configured to acquire information about a subject by using an electric signal output from the device,
wherein the device receives an acoustic wave from the subject and converts the acoustic wave into the electric signal.

14. The subject information acquisition apparatus according to claim 13, further comprising:
a light source,
wherein the device receives a photoacoustic wave generated by irradiation of the subject with light emitted from the light source and converts the photoacoustic wave into the electric signal, and
wherein the processing unit acquires the information about the subject by using the electric signal from the device.
